(19) United States
(12) Patent Application Publication
(10) Pub. No.: US 2002/0094602 A1
(43) Pub. Date: Jul. 18, 2002

(54) DCA memory module and a fabrication method thereof

(76) Inventors: Tzong-Dar Her, Taichung (TW); Chi-Chuan Wu, Taichung (TW)

Correspondence Address: J.C. Patents, Inc., 4 Venture, Suite 250, Irvine, CA, 92618, US

(21) Appl. No.: 09/990,160

(22) Filed: Nov. 20, 2001

(30) Foreign Application Priority Data
Jan. 17, 2001 (TW) 90101004

(51) Int. Cl. H01L 21/66; H01L 21/44; H01L 21/48; H01L 21/50; H01L 23/48; H01L 23/52; H01L 29/40; H01L 23/28; H01L 23/34

(52) U.S. Cl. 438/106; 438/110; 438/113; 438/127; 257/723; 257/782; 257/787

(57) ABSTRACT

A DCA memory module. The memory module has a substrate, at least a chip set and a molding compound. The chip set is adhered on the substrate and is electrically connected to the substrate. The chip set has a plurality of chips formed side by side as one group, and each chip is electrically connected to each other by a plurality of circuits. The molding compound encapsulates at least a portion of the electrical connection between the chip set and the substrate.

### CROSS-REFERENCE TO RELATED APPLICATION

This application claims the priority benefit of Taiwan application serial no. 90101004, filed Jan. 17, 2001.

### BACKGROUND OF THE INVENTION

1. Field of Invention

The present invention relates generally to a direct chip attach (DCA) memory module and a fabrication method thereof More particularly, the present invention relates to a simplified method of fabricating a DCA memory module to reduce the package size, time consuming and cost.

2. Description of the Related Art

The demands of advanced electronic technology requires electronic products to be made lighter, thinner, faster and smarter while simultaneously making them more friendly, powerful, reliable, robust and less expensive. Thus, the trend for electronic packages is to develop highly-integrated packaging structures. The direct chip attach (DCA) technology directly attaches a memory chip onto a substrate of a memory module. Then a wire bonding or flip-chip process is carried out to electrically connect the memory chip to the substrate of the memory module. The packaging process of the chips is simplified and the contact path between the chip and the substrate can be reduced. Therefore, the packaging size is decreased and the reliability of the memory device is improved.

FIG. 1 illustrates a diagrammatic view of a packaging structure of a conventional memory module. The conventional method of packaging a memory module utilizes a lead on chip (LOC) package in order to have a package with reliable and good electrical properties. In the conventional method of packaging chips, a memory chip 110 and a lead frame (not shown) are first provided. The memory chip 110 comprises an active surface 112, and a plurality of bonding pads 114 are formed on the active surface 112. A plurality of leads 120 are formed on the lead frame, one end of the each lead 120 is an inner lead 122 and another end of each lead 120 is an external lead 124. Next, the leads 120 are adhered onto the active surface 112 of the memory chip 110 by tapes 140. A wire bonging process is carried out to electrically connect the bonding pads 114 of the memory chip 110 to the inner leads 122 by a plurality of conductive wires 130. A molding process is carried out to encapsulate the memory chip 110, the inner leads 122 and the conductive wires 130. The external leads 124 are exposed. A singulation process is carried out to form an individual packaging unit 100. A substrate 160 of the memory module comprises nodes 162. A mounting process is carried out to electrically connect the external leads 124 to the nodes 162 of the substrate 160 by a surface mount technology (SMT).

In the above-mentioned package, a signal from the memory chip 110 is transmitted through the conductive wire 130 to the inner leads 122 and then to the external leads 124. Finally the signal is transmitted to the nodes 162 of the substrate 160 of the memory module. However, this type of structure causes the conductive path to be too long, leading to undesirable electrical functions. Therefore, the conventional packaging structure is not suitable for a high-speed memory module device.

### SUMMARY OF THE INVENTION

It is an object of the present invention to provide a package structure of a DCA of a memory module and a fabrication method thereof that reduces cost and simplifies the fabrication process. It is another object of the present invention to provide a DCA of a memory module and a fabrication method thereof to reduce the package size of the memory module. It is another object of the present invention to provide a DCA of a memory module and a fabrication method thereof to improve the electrical properties of the device and reduce the fabricating time.

To achieve the foregoing and other objects and in accordance with the purpose of the present invention, the present invention provides a substrate, at least a chip set and a molding compound. The chip set is adhered on the substrate and is electrically connected to the substrate. The chip set comprises a plurality of chips, and each chip is electrically connected to each other by a plurality of connecting circuits. The molding compound encapsulates at least a portion of the electrical connection between the chip set and the substrate.

According to a preferred embodiment of the present invention, a substrate comprises a plurality of patterned-trace layers and an insulating layer, which is located in between the patterned-trace layers to form an electrical insulation between the patterned-trace layers. A plurality of conductive vias are formed in the insulating layer, and they electrically connect the patterned-traces layers to each other. The insulating layer is made of a material selected from a group consisting of glass epoxy resin (FR-4, FR-5), bismaleimide-triazine (BT), epoxy resin or polyimide. The patterned-trace layers are formed by defining a copper foil with a photolithography method, and the chip set is electrically connected to the substrate by a flip-chip technology or a wire bonding method. The chip set comprises one of an even number of chips selected from a group of two, four or eight chips formed side by side, for example, the chip set can comprise a group of eight chips formed side by side as one group. A total number of chips in the DCA memory module is eight or sixteen.

Another preferred embodiment of the present invention provides a wafer having a plurality of chips. A first test is performed to test the chips on the wafer and a burn-in test is followed. A second test is performed to test the chips on the wafer. A singulating process is carried out to separate the chips into a plurality of chip sets, wherein each chip set comprises at least two chips formed side by side as a group. A substrate of the memory module is provided. At least a chip set is adhered on a surface of the substrate of the memory module according to the needs of the memory module, wherein the chip set is electrically connected to the substrate of the memory module. A molding compound encapsulates at least a portion of the electrical connection between the chip set and the substrate of the memory module.

Another preferred embodiment of the present invention provides a plurality of chip sets which have a plurality of circuits connecting the chips to each other. The chip set is electrically connected to the substrate by a flip-chip technology or a wire bonding method. The chip set comprises one of an even number of chips selected from a group of two, four or eight chips formed side by side, for example, the chip set can comprise a group of eight chips formed side by side. A total number of chips in the DCA memory module is eight or sixteen.

Both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 is a diagrammatic view of a packaging structure of a conventional memory module.

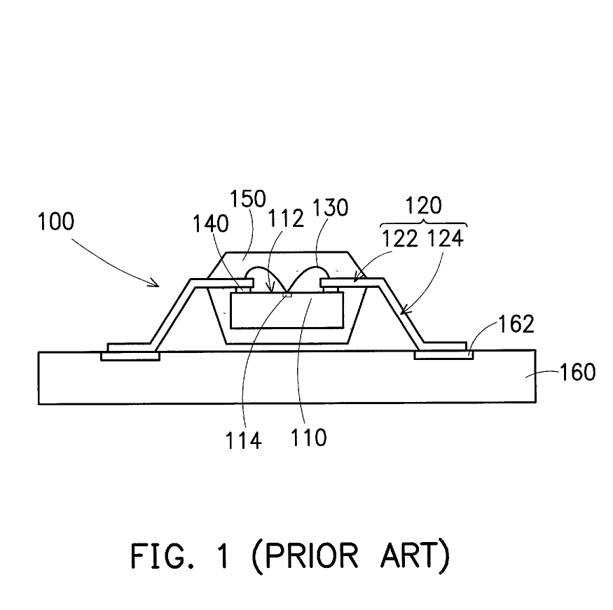

FIG. 2 is a top view of a memory wafer.

FIG. 3 is a magnified cross-sectional view of chips in a chip set corresponding to FIG. 2.

FIG. 4 is a diagrammatic view of a DCA memory module in accordance with a first preferred embodiment of the present invention.

FIG. 5 is a schematic cross-sectional view taken along a line I-I of FIG. 4.

FIG. 6 is a magnified view of chips in a chip set corresponding to FIG. 2 in accordance with a second embodiment of the present invention.

FIG. 7 is a diagrammatic top view of a DCA memory module in accordance with a third embodiment of the present invention.

FIG. 8 is a schematic cross-sectional view taken along a line II-II of FIG. 7.

FIG. 9 is a diagrammatic top view of a DCA memory module in accordance with a fourth embodiment of the present invention.

### DESCRIPTION OF THE PREFERRED EMBODIMENTS

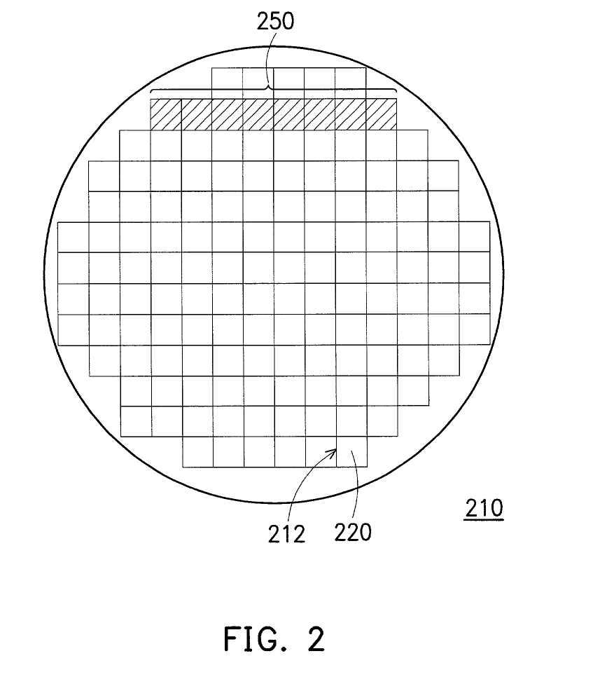

FIGS. 2 to 4 illustrate diagrammatic views of a fabrication process of a DCA memory module in accordance with a first embodiment of the present invention.

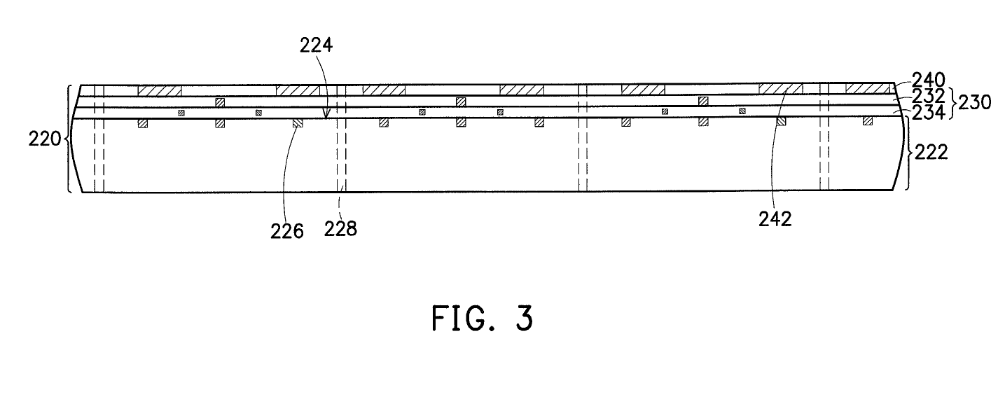

FIG. 2 is a diagrammatic top view of the memory wafer, and FIG. 3 is a magnified view of chips in a chip set corresponding to FIG. 2. A wafer 210 is first provided and it comprises chips 220. A scribe-line 212 is located in between each chip 220. Referring to FIG. 3, each chip 220 comprises a substrate 222, which has a first surface 224. Semiconductor devices 226 is located in the first surface 224 of the substrate 222. A multilevel-interconnection 230 is formed on the first surface 224 of the substrate 222. The multilevel-interconnection 230 is formed a sandwich-like layer, which comprises at least a metal layer 232 and an insulating layer 234 alternating, wherein the metal layer 232 and the insulating layer 234 stacked and internally connected to form a multilevel interconnection. A plurality of vias (not shown), which are formed in the insulating layer 234, are utilized to electrically connect the metal layer 232, or to the semiconductor device 226. A plurality of circuits (not shown) is formed in the metal layer 232, and the circuits electrically connect each chip 220 to each other. A passivation layer 240 is formed on the multilevel interconnection 230. A plurality of bonding pads 242 are formed on the metal layer 232. The bonding pads 242 serve as external nodes for the multilevel interconnections. In FIG. 3, dotted lines 228 indicate regions of a portion of scribe-line 212 in FIG. 2.

A first test is carried out to determine whether the circuits on the chips 220 are functional. Once the chips 220 pass the first test, a burn-in test is followed, wherein the wafer 210 is subjected to high current and high temperature. The burn-in test indicates the stability of the circuits on the chips 220 of the wafer 210 under those conditions. Afterwards, another test is conducted to determine if the circuits still function normally. The main purpose of these tests is to ensure the quality of the chips 220.

A singulating process is performed to separate chips 220 into a plurality of chip sets 250, wherein each chip set 250 can comprises a plurality of chips, such as 8 chips 220, according to the requests of the memory module.

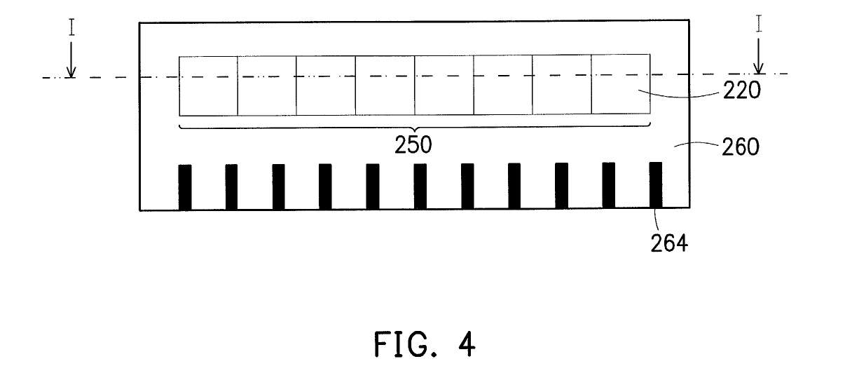

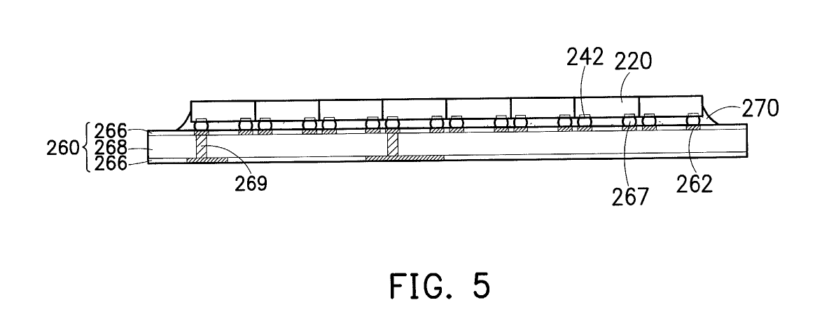

FIG. 4 illustrates a diagrammatic view of the DCA of the memory module in accordance with a first embodiment of the present invention. FIG. 5 is a schematic cross-sectional view taken along a line I-I of FIG. 4. When the fabrication of chip set 250 is completed, a substrate 260 of the memory module is provided and is formed a sandwich-like layer by stacking a plurality of patterned-trace layers 266 and an insulating layer 268 alternating. The insulating layer 268 is located in between the patterned-trace layers 266, and a plurality of vias 269 are formed in the insulating layer 268 to electrically connect the patterned-trace layers 266 to each other. The insulating layer 268 is made of a material selected from a group consisting of glass-epoxy resin (FR-4, FR-5), bismaleimide-triazine (BT), epoxy resin or polyimide. The patterned-trace layer 266 is defined by photolithographing a copper foil. A solder mask is applied onto a surface of the substrate 260 of memory module. This structure is well known in the art; thus, the detailed description is omitted.

A plurality of internal nodes 262 and a plurality of external nodes 264 are formed on the substrate 260 of memory module. The external nodes 264 can be electrically connected to the external circuits (not shown). The internal nodes 262 correspond to the bonding pads 242 of the chips 220. The substrate 260 of memory module can carry approximately 8 to 16 chips, and a substrate 260 of memory module comprising 8 chips is utilized as an example in the embodiment of the present invention.

A flip-chip technology is applied to electrically connect the bonding pads 242 of each chip 220 to the corresponding internal nodes 262 by utilizing a plurality of bumps267. A molding process is performed to fill gaps between the chip sets 250 and the substrate 260 of the memory module with a molding compound 270, which encapsulates the bumps 267.

Referring to FIGS. 2 to 5, in the above-mentioned fabrication process, the chips 220 on the wafer 210 are cut into chip sets 250. Each chip set 250 is electrically connected to the substrate 260 of the memory module; therefore the chips 220 on the chip set 250 can be connected simultaneously to the substrate 260 of memory module. Thus the time of working with the memory module can be reduced. The chips 220 are electrically connected directly to the substrate 260 of memory module without any carrier; therefore the fabricating process can be simplified. Since no carrier is required, the cost of fabrication is reduced. On the other hand, a plurality of chips 220 are located and packaged as a set 250; thus, a packaging size of the chip set 250 is smaller than the chips 220 that are packaged individually. The area of the substrate 260 of the memory module can be reduced. Further more, the chip sets 250 are electrically connected directly to the substrate 260 of memory module. A connecting distance between the chips 220 and the substrate 260 is tremendously reduced and a decreased connecting distance can reduce problems of signal delay and transmission degradation. The reliability of the memory module is thus increased. For one of the chip sets 250, the circuits between the chip sets 250 are not separated and a plurality of circuits (not shown) are formed in the metal layer 232 of the chips 220. Thus the chips 220 can electrically connect to each other, and each chip 220 can reduce its external circuit structure. Therefore, the number of bonding pads 242 and bumps 267 can be reduced. Due to this structure, the connecting circuits between the chips 220 can be electrically connected with each other in the multilevel interconnection. The whole circuit of the substrate of the memory module 260 is thus simplified, and the area of the substrate 260 of the memory module is reduced.

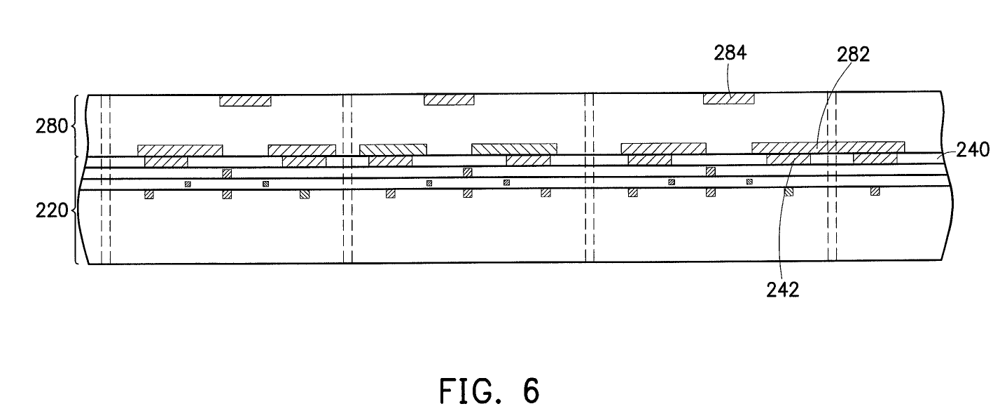

FIG. 6 illustrates a magnified view of a set of chips corresponding to FIG. 2 in accordance with a second embodiment of the present invention. The above-described first embodiment utilizes a plurality of circuits of the metal layer in the chips to electrically connect to each chip. However, the electrical connecting method is not limited to the above-mentioned method. A redistribution layer 280 can be formed on the passivation layer 240, and a plurality of circuits 282 and external bonding pads 284 are formed in the redistribution layer 280. The circuits 282 are electrically connected to the external bonding pads 284, and each bonding pad 242 of the chips 220 are electrically connected to each other. Thus the external circuit of each chip 220 can be simplified. The number of the external bonding pads 284 is decreased, and the external bonding pads 284 are electrically connected to the nodes (not shown) of the substrate 260 of the memory module.

From the above-mentioned first and second embodiments, the connecting circuits between the chips are located in the metal layer or in the redistribution layer instead within the substrate of the memory module. Thus the layout of the substrate of the memory module is simplified, and the area of the substrate of the memory module is substantially reduced.

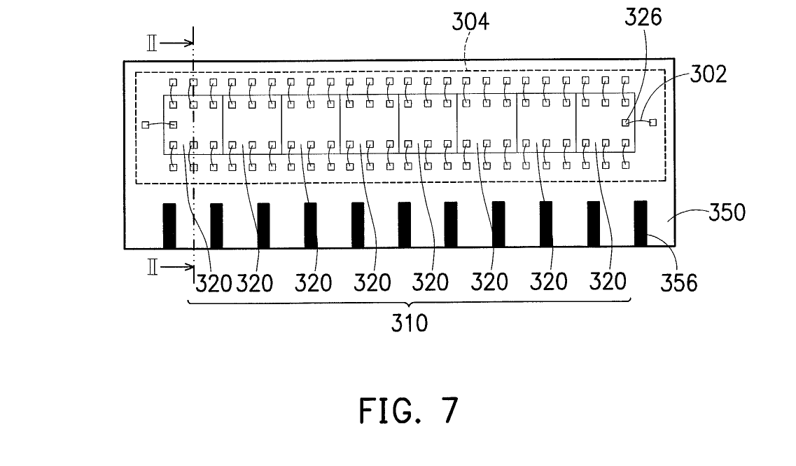

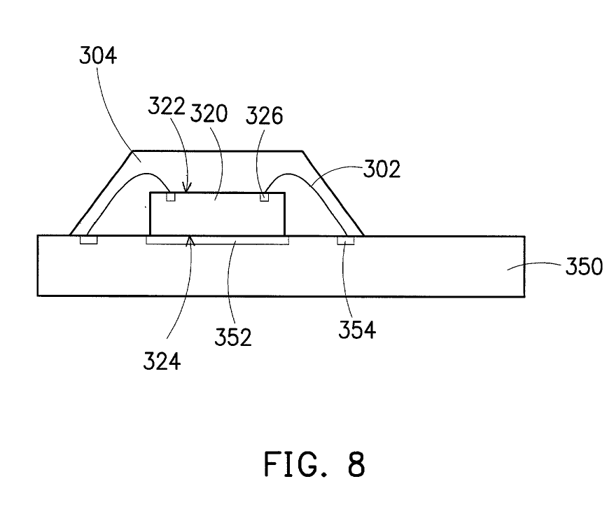

FIG. 7 illustrates a diagrammatic top view of a DCA memory module in accordance with a third embodiment of the present invention. FIG. 8 illustrates a schematic cross-sectional view taken along line II-II of FIG. 7. The third embodiment utilizes a wire bonding method to electrically connect the chips to the substrate of the memory module. The steps of fabrication are described as follows. A substrate 350 of the memory module comprises at least a chip set pad 352, a plurality of internal nodes 354 and a plurality of external nodes 356. The internal nodes 354 are located around the periphery of the chip set pad 352 and can electrically connect to the external circuits (not shown) by the external nodes 356. At least a chip set 310 is provided, and each chip set 310 comprises a plurality of chips 320. A chip set 310 comprising eight chips is used as an example in the third embodiment. Each chip 320 has an active surface 322 and a corresponding back surface 324. A plurality of bonding pads 326 are formed on the active surface 322. The chip sets 310 are adhered on the chip set pad 352, and the back surface 324 of each chip 320 in the chip sets 310 is adhered on the chip set pad 352. A wire bonding method is performed to electrically connect the bonding pads 326 of each chip 320 to the corresponding internal nodes 354 by a plurality of wires 302. Next, a molding process is carried out to encapsulate the chip sets 310, wires 302, internal nodes 354 and bonding pads 326.

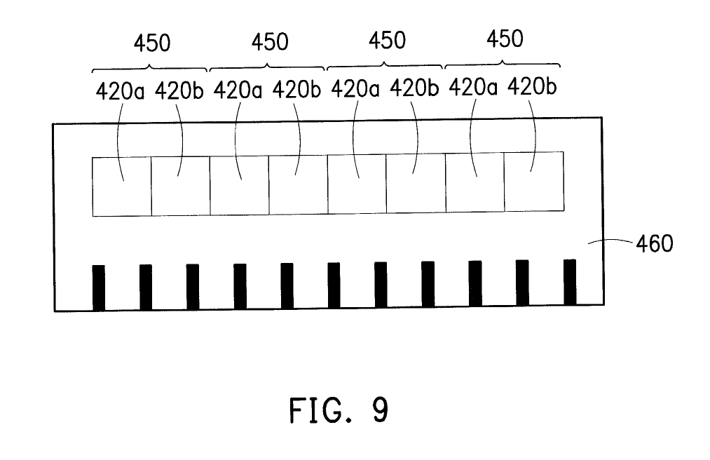

FIG. 9 illustrates a diagrammatic top view of a DCA method of fabricating a memory module in accordance with a fourth embodiment of the present invention. Since the number of chips 320 in each chip set 310 is not restricted and limited according to the above-mentioned embodiments, a chip set 310 comprising two chips 320 is used as an example in the fourth embodiment of the present invention. A substrate 460 of the memory module comprises four chip sets 450, and each chip set 450 comprises two chips 420a, 420b. The chips 420a and 420b are electrically connected to each other through a plurality of circuits of the metal layer in the chips such as 420a and 420b, or by utilizing a redistribution layer to electrically connect to each other. Wire bonding or flip-chip technology can be used to electrically connect the chips to the substrate 460 of the memory module. Flip-chip technology is utilized as an example in this embodiment. When the chip set comprises a few chips, such as two chips, the connecting circuits between the chips can be simplified; thus, the yield of the chip set is improved and the process window of the product is increased.

From the above-described embodiments, the advantages of the present invention are as follows:

1. The present invention provides a DCA memory module and a method of fabricating a memory module to separate chips sets in accordance with a set of a predetermined amount of chips to serve as a singulating unit. The chip set is electrically connected to a substrate of the memory module. Thus the chips in the chip set are simultaneously also bonded on the substrate of the memory module. The fabricating process is simplified and less time is required. The cost of the production is reduced.

2. The present invention utilizes a plurality of chips in one set, and they are molded together. Thus, the size of the package is reduced, and the area of the substrate of the memory module is reduced as well.

3. The present invention also provides the electrical connection of the chips directly to the substrate of the memory module. The connecting distance is reduced and the signal transmission is improved. Thus the electrical performance of the memory module is tremendously improved.

4. Since the chips in the chip set will not be separated, the connecting circuit between the chips can be formed in the metal layer of the chips or in the redistribution layer to electrically connect each chip. Thus the external circuits of the chips can be simplified, and the whole copper trace of the substrate of the memory module can be simplified. The area of the substrate is thus reduced.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A DCA memory module, comprising:
a substrate;
at least a chip set having a plurality of chips formed side by side with each other, wherein the chips are adhered on the substrate and are electrically connected to the substrate, a plurality of circuits are located between the chips and electrically connect the chips to each other; and
a molding compound, encapsulating a portion of the electrical connection between the chip set and the substrate.

2. The DCA memory module of claim 1, wherein the substrate comprises;
a plurality of patterned-trace layers; and
at least an insulating layer located in between the patterned-trace layers, wherein a plurality of vias are formed in the insulating layer and electrically connect the patterned-trace layers to each other.

3. The DCA memory module of claim 2, wherein the insulating layer is made of a material selected from a group consisting of glass epoxy resin (FR-4, FR-5), bismaleimide-triazine (BT), epoxy resin or polyimide.

4. The DCA memory module of claim 2, wherein the line-patterned layers are formed by defining copper foil using photolithography.

5. The DCA memory module of claim 1, wherein the chip set is electrically connected to the substrate by a flip-chip technology, and the molding compound fills into a gap located between the chip set and the substrate.

6. The DCA memory module of claim 1, wherein the chip set is electrically connected to the substrate by a plurality of conductive wires, and the molding compound encapsulates the chip set and the conductive wires.

7. The DCA memory module of claim 1, wherein the chip set comprises an even number of chips formed side by side as one group.

8. The DCA memory module of claim 1, wherein the chip set comprises an even number chips and a total number of chips in the DCA memory module is eight.

9. The DCA memory module of claim 1, wherein the chip set comprises an even number chips and a total number of chips in the DCA memory module is sixteen.

10. The DCA memory module of claim 8, wherein the chip set comprises one of the number of the chips selecting from a group of two, four or eight chips.

11. The DCA memory module of claim 9, wherein the chip set comprises one of the number of the chips selecting from a group of two, four or eight chips.

12. A DCA memory module, comprising:
a substrate;
at least a chip set, for adhering onto the substrate and electrically connecting to the substrate, wherein the chip set has a plurality of chips formed side by side as one group; and
a molding compound, for encapsulating a portion of the electrical connection between the chip set and the substrate.

13. The DCA memory module of claim 12, wherein the chip set is electrically connected to the substrate by a flip-chip technology, and the molding compound fills into a gap located between the chip set and the substrate.

14. The DCA memory module of claim 12, wherein the chip set is electrically connected to substrate by a plurality of conductive wires, and the molding compound encapsulates the chip set and the conductive wires.

15. The DCA memory module of claim 12, wherein the chip set comprises eight chips formed side by side as one group.

16. The DCA memory module of claim 12, wherein the chip set comprises an even number chips and a total number of chips in the chip set is eight.

17. The DCA memory module of claim 12, wherein the chip set comprises an even number of chips and a total number of chips in the chip set is sixteen.

18. The DCA memory module of claim 16, wherein the chip set comprises one of the number of the chips selecting from a group of two, four or eight chips.

19. The DCA memory module of claim 17, wherein the chip set comprises one of the number of the chips selecting from a group of two, four or eight chips.

20. A method of fabricating a DCA memory module, comprising:
providing a wafer having a plurality of chips;
performing a first test, for testing the chips on the wafer;
performing a burn-in test;
performing a second test, for testing the chips on the wafer;
performing a cutting process, for separating the chips into a plurality of chip sets, wherein each chip set comprises at least two chips formed side by side as a group;
providing a substrate of the memory module;
adhering the chip sets on a surface of the substrate of the memory module according to the number of the chip required from the DCA memory module, wherein the chip sets are electrically connected to the substrate of the memory module; and
encapsulating at least a portion of the electrical connection between the chip set and the substrate of the memory module with a molding compound.

21. The method of claim 20, wherein the chips in the chip set are electrically connected to each other by a plurality of circuits within the chips.

22. The method of claim 20, wherein the chip set is electrically connected to the substrate by a flip-chip technology, and the molding compound fills into a gap located between the chip set and the substrate.

23. The DCA memory module of claim 20, wherein the chip set is electrically connected to the substrate by a plurality of conductive wires, and the molding compound encapsulates the chip set and the conductive wires.

24. The DCA memory module of claim 20, wherein the chip set comprises eight chips formed side by side.

25. The DCA memory module of claim 20, wherein a total number of chips in the DCA memory module is eight.

26. The DCA memory module of claim 24, wherein a total number of chips in the DCA memory module is sixteen.

27. The DCA memory module of claim 25, wherein the chip set comprises one of the number of chips selecting from a group of two, four or eight chips.

28. The DCA memory module of claim 26, wherein the chip set comprises the chip set comprises one of the number of chips selecting from a group of two, four or eight chips.
